(19) United States
(12) Patent Application Publication
(10) Pub. No.: US 2006/0145163 A1
(43) Pub. Date: Jul. 6, 2006

(54) Organic elctroluminescent display and method for manufacturing organic electroluminescent display

(76) Inventors: Takatoshi Tsujimura, Kanagawa (JP); Mitsuo Morooka, Kanagawa (JP); Kelgo Kanoh, Kanagawa-ken (JP); Kohichi Miwa, Kanagawa (JP)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(21) Appl. No.: 10/528,756

(22) PCT Filed: Sep. 12, 2003
(86) PCT No.: PCT/JP03/11746

§ 371 Date: Dec. 15, 2005

(30) Foreign Application Priority Data
Sep. 17, 2002 (JP) 2002-269834

(51) Int. Cl. H01L 29/08

(52) U.S. Cl. 257/79; 257/40

(57) ABSTRACT

An organic light emitting diode device of the present invention comprises a substrate, a light-transmissive electrode formed on the substrate, a coating-film-formative function layer including a hole transport material and an electron transport material, the function layer being formed on the substrate, trench patterns formed on the function layer, dopant doped into the function layer between walls forming these trench patterns, and a light-reflective electrode coating the trench patterns. The dopant is introduced into the trench patterns by a capillary phenomenon, thus enabling high-definition color patterning. Moreover, the present invention provides a method for manufacturing the above-described organic light emitting diode device.

### BACKGROUND OF THE INVENTION

The present invention relates to organic electroluminescence (hereinafter, abbreviated as “organic EL”), and more specifically, to an organic EL display device capable of a high-definition display, for which color patterning by a dopant is performed, and relates to a method for manufacturing an organic EL device for which the color patterning is performed.

An organic EL device has a very fast response speed and is a self-luminous device, and therefore, when the EL device is applied to a display apparatus, it is expected that a good flat display apparatus with a wide viewing angle can be provided. In this connection, application of the organic El device to the flat display apparatus succeeding a liquid crystal display apparatus is studied.

When the above-described organic EL device is applied to the flat display apparatus, a color pattern having characteristics of red (R), green (G) and blue (B) lights is formed thereon in order to perform a color display in many cases. For forming such a color pattern as described above, a patterning method by use of a shadow mask, a method for patterning by use of an ink-jet printer, and the like have been heretofore proposed.

Although the method for performing color patterning by use of the shadow mask can perform good patterning, the method has had a disadvantage in that alignment accuracy on the patterning is lowered due to the alignment accuracy of the manufactured shadow mask and the thermal expansion and deformation of the shadow mask itself. Moreover, though the color patterning is also enabled by the method for patterning by use of an ink-jet printer, it has been known that the method has had a disadvantage in that an error due to low accuracy of ink-jet nozzles, variations of an ink discharge amount or the like is large.

Moreover, besides the above, a method has been known, in which a solution containing dopant is used, and doping is performed by stamping. FIG. 8 shows luminescence characteristics of a doping pattern obtained by the stamping. Although the color patterning is enabled also by the stamping, the method has had a disadvantage of being insufficient in accuracy, homogeneity and reproducibility, and further being incapable of color patterning with sufficient accuracy.

Because of the above-described disadvantages, color patterning with a definition as high as that of the liquid crystal display apparatus (approximately 200 ppi) has been impossible in the conventional organic EL display device. Specifically, there has heretofore been a demand for a method of performing color patterning for the organic EL device so as to provide thereto a high definition of approximately 200 ppi or more and an organic EL display device manufactured by use of the method.

### SUMMARY OF THE INVENTION

The present invention was made under a conception that high-definition color patterning would be able to be performed easily and securely if the solution containing the dopant could be introduced into an organic El material layer by use of a capillary phenomenon when a color pattern is formed by performing doping for an organic EL material.

Specifically, the present invention forms trenches formed of photoresist adjacently to the organic EL material layer with desired accuracy. The trenches are formed with a size that is sufficiently fine and capable of introducing the solution containing the dopant into the organic EL material layer by the capillary phenomenon. The introduced dopant is dispersed into the organic EL material layer simultaneously with drying of a solvent by baking treatment, and thus the doping for the organic EL material layer is performed.

In accordance with accuracy of a pattern of the photoresist formed adjacently to the organic El material layer and with a pattern configuration thereof, the accuracy of the color patterning is defined, and patterning for the full-color display is enabled. Although the photoresist pattern is left after the doping, no optical disadvantage occurs even if the pattern of the photoresist layer remains because the photoresist used in the present invention is optically transparent and achromatic. Moreover, in the present invention, the trench pattern can be formed in such a manner that a wall is directly formed from an electrode before forming a function layer. Furthermore, in preferred embodiments of the present invention, the trench pattern can be formed on the function layer.

Specifically, the present invention provides an organic light emitting diode device, comprising:

a substrate;

a first electrode formed on the substrate;

an organic EL function layer formed on the substrate; a trench pattern formed adjacently to the function layer; and

a second electrode layer formed on the function layer and the trench pattern.

The function layer in the present invention can contain polymer or oligomer having an amine derivative structure. In the present invention, different types of dopant can be contained in areas of the function layer, the areas being adjacent to each other while being spaced by a wall of the trench pattern. In the present invention, it is preferable that a doping concentration in the function layer under the wall forming the trench pattern be lower than in other portions.

The present invention can provide a method for manufacturing an organic light emitting diode device, the method comprising the steps of:

forming a first electrode on a substrate;

forming an organic EL function layer and a trench pattern on the electrode; and

forming a second electrode layer on the function layer and the trench pattern.

In the present invention, the step of forming a function layer and a trench pattern can include the steps of:

forming the function layer; forming a photoresist layer on the function layer; and patterning the photoresist layer into the trench pattern.

In the present invention, the manufacturing method can further comprise the step of introducing, along the trench pattern, at least a second function layer having a composition different from that of the function layer. According to the present invention, the manufacturing method can further comprise the step of performing doping for the function layer by supplying a dopant solution along the trench pattern.

In the present invention, the step of performing doping for the function layer by supplying a dopant solution can include the steps of:

supplying the dopant solution along the trench pattern; and

dispersing the dopant into the function layer by heating the function layer.

In the present invention, the step of performing doping can include the step of supplying different types of dopant into areas of the function layer, the areas being spaced by a wall of the trench pattern.

### BRIEF DESCRIPTION OF THE DRAWINGS

For a more complete understanding of the present invention and the advantages thereof, reference is now made to the following description taken in conjunction with the accompanying drawings.

FIG. 1 is a perspective view illustrating an organic EL display device of the present invention.

FIG. 2 is a cross-sectional view illustrating the organic EL display device illustrated in FIG. 1 along an arrow B-B.

FIGS. 3(a) to 3(c) are views partially showing a manufacturing process of the organic EL display device of the present invention.

FIGS. 4(a) and 4(b) are views partially showing the manufacturing process of the organic EL display device of the present invention.

FIG. 5 is a perspective view illustrating the organic EL display device of the present invention in detail.

FIG. 6 is a view illustrating another embodiment of the organic EL display device of the present invention.

FIG. 7 is a view showing a doping pattern of the organic EL display device of the present invention.

FIG. 8 is a view showing a doping pattern obtained by stamping.

### DETAILED DESCRIPTION OF THE PREFERRED EMBODIMENTS

Although the present invention will be described below by means of embodiments illustrated in the drawings, the present invention is not limited to the embodiments illustrated in the drawings.

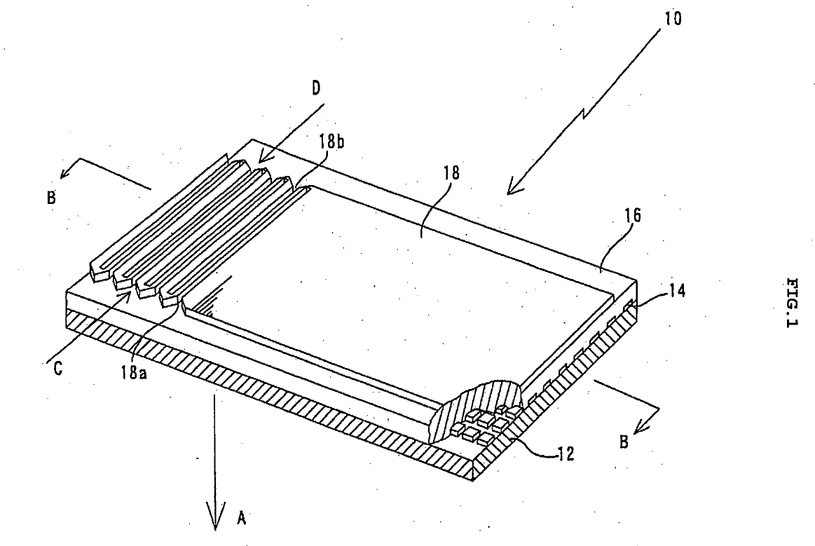

FIG. 1 is a partially cross-sectional perspective view illustrating a structure of an organic EL display device of the present invention. The organic EL display device 10 illustrated in FIG. 1 emits light generated by electroluminescence to the direction of the arrow A. In the organic EL display device 10 of the present invention, the anode 14 made of a transparent conductive film is deposited on the substrate 12 such as glass, and is patterned. In FIG. 1, in order to show the patterned anode 14 distinctly, a part of the structure on the substrate 12 of the organic EL device is cut away, thus showing the patterned anode 14. Moreover, the function layer 16 for generating luminescence by the electroluminescence is deposited on the anode 14. The photoresist layer 18 formed of photoresist is formed on the upper surface of the function layer 16 in FIG. 1, and the trench patterns 18a and 18b separated by a wall are patterned on the photoresist layer 18. The trench patterns 18a and 18b are formed in parallel to one another so as to be approximately orthogonal to the patterned anode 14. Furthermore, on the photoresist layer 18, an unillustrated light-reflective electrode is formed and emits the light to the direction of the arrow A.

In the configuration of the bottom emission type as a specific embodiment described in the present invention, as a material forming the anode 14, any material can be used as long as it is transparent and conductive. For example, ITO, IZO, SnO₂ or the like can be used. Moreover, in the case of adopting a configuration of a top emission type in the present invention, the anode 14 may not necessarily be transparent, and Al, Ni, Ni/Al, Cr, Ag or the like can be used as the anode. It is preferable that the function layer 16 usable in the present invention have solvent resistance and coating film strength so as to be able to form the trench patterns 18a and 18b by coating the photoresist. For this purpose, an oligomeric carrier transport material and a polymeric carrier transport material can be used, and polyvinylcarbazole and the like can be listed in the specific embodiment of the present invention. The oligomeric carrier 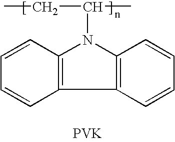
transport material in the present invention is defined as any carrier transport material having a molecular weight ranging between that of a monomeric carrier transport material and that of the polymeric carrier transport material, which will be shown below. The polymeric carrier transport materials usable in the present invention will be exemplified below.

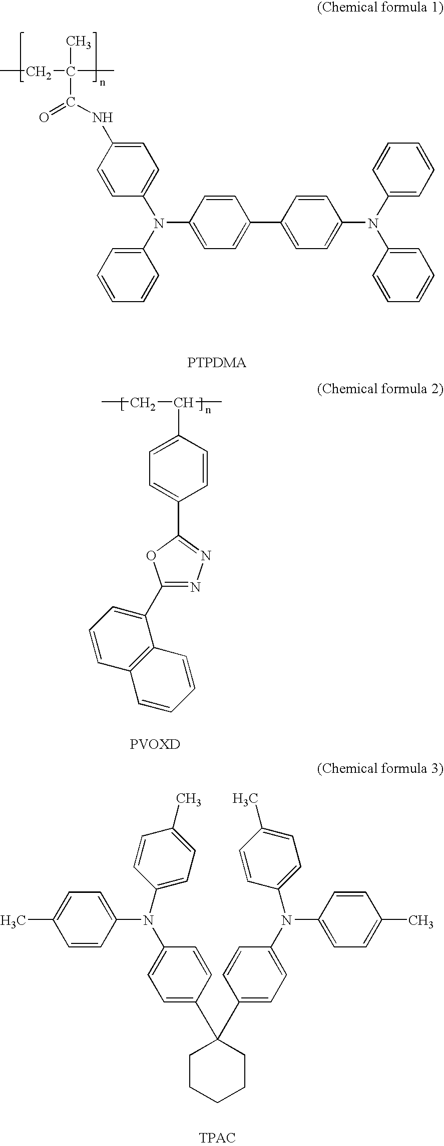

In the present invention, besides the above-described polymeric carrier transport materials, carrier transport materials are usable, which are obtained by mixing a carrier 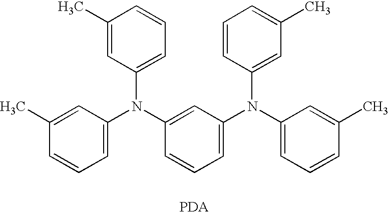
transport material with resin having optically good characteristics, such as polymethylmethacrylate resin, polycarbonate resin and epoxy resin. As the carrier transport material that can be mixed with the resin components to be used, for example, materials shown below are usable.

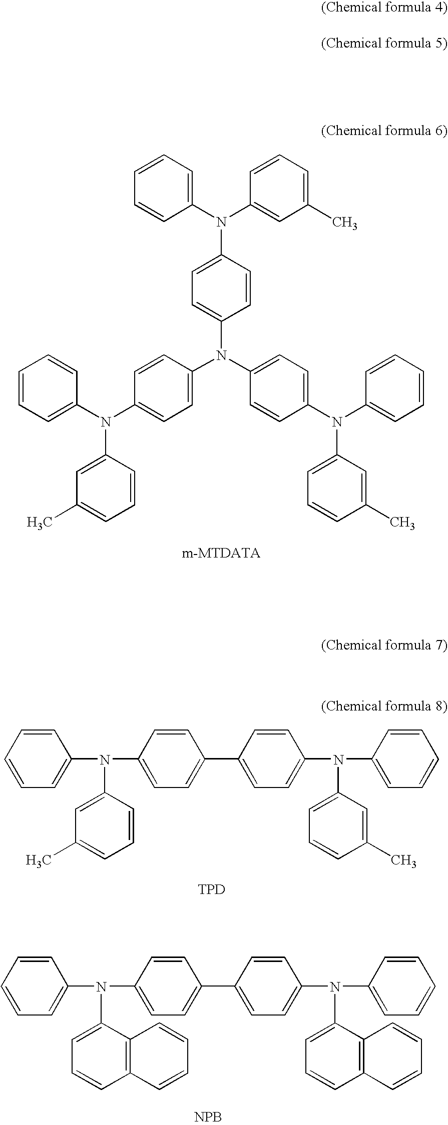

Moreover, as electron transport layers usable in the present invention, materials exemplified below can be listed.

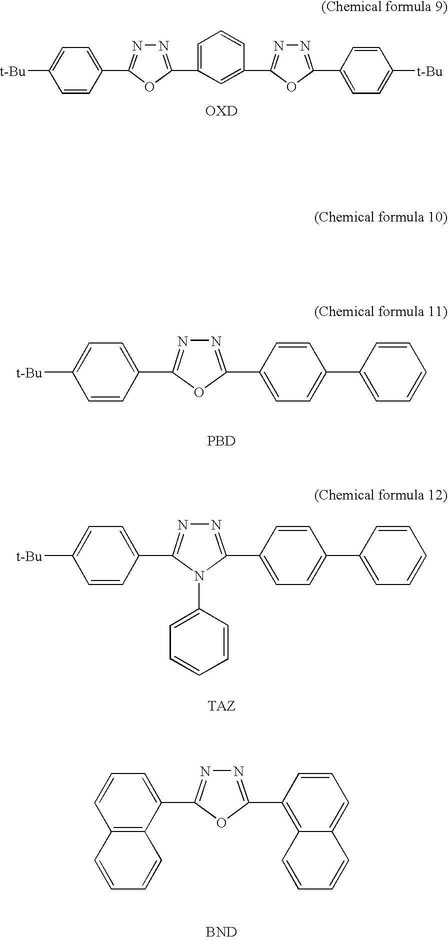

Furthermore, a luminescent material is usable according to needs in the present invention, and as the luminescent materials usable in the present invention, for example, besides a complex such as 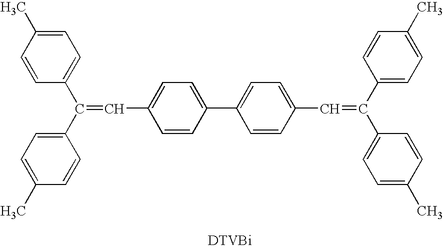
Alq3, any luminescent low-molecular or high-molecular materials known heretofore are usable. The luminescent materials usable in the present invention will be described below in an exemplifying manner.

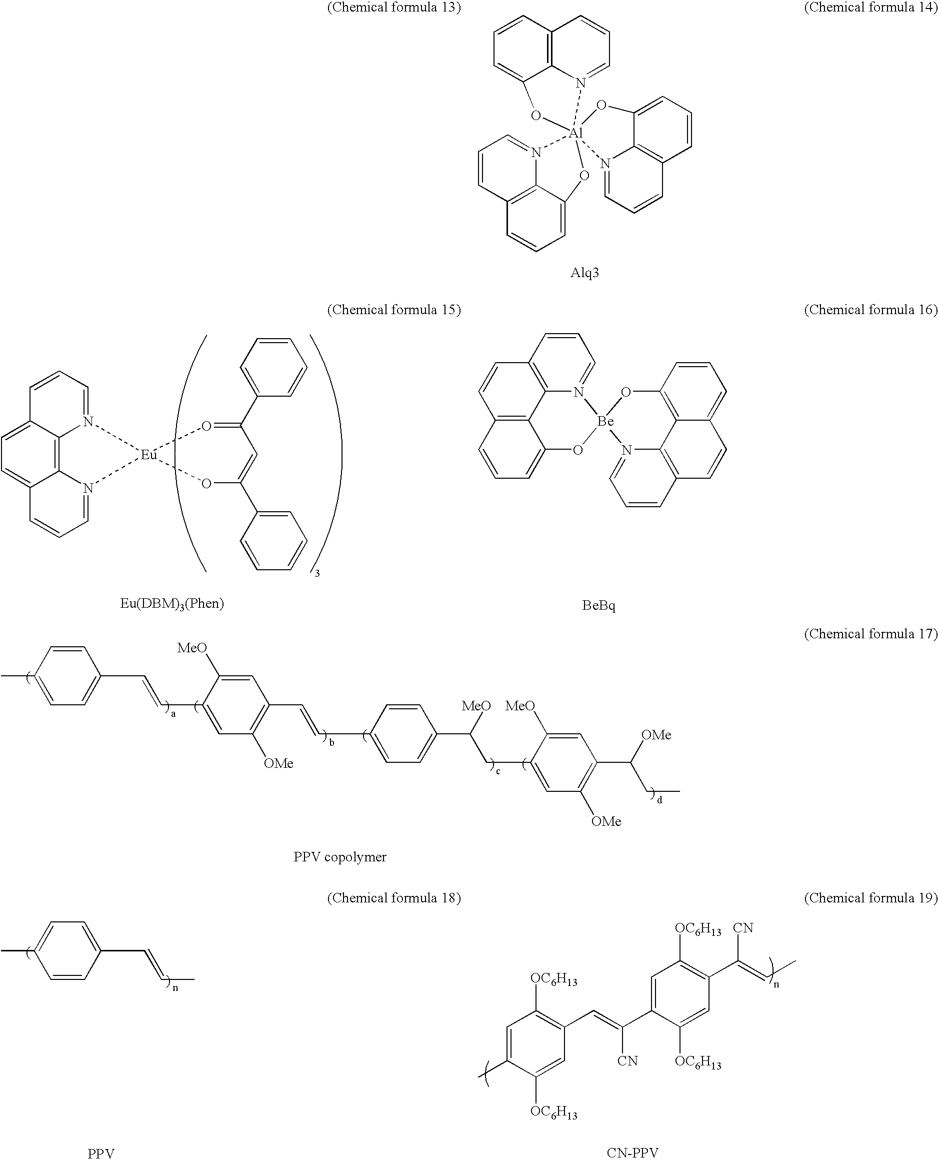

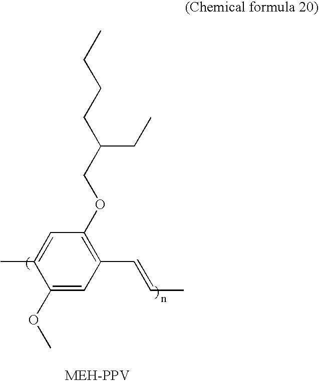

Furthermore, in the present invention, though the above-described function layer 16 is described as a single layer in the specific embodiment of the present invention, it is also possible to configure the function layer 16 by including a plurality of layers such as a hole transport layer, a luminous layer and an electron transport layer according to needs.

As the photoresist usable for forming the trench pattern in the present invention, any positive or negative photoresist known heretofore is usable. Specifically, as the positive photoresist, a composition obtained by mixing a photosensitive material with phenolic novolac, a so-called acid-dissociative photoresist mixed with a photo acid generator, which uses polyvinylphenol alkyl ester, and the like can be listed. Moreover, as the negative photoresist, any is usable as long as it uses photopolymerization. For example, acrylate, epoxy and acid-dissociative photoresist are usable. Particularly, in the present invention, the negative photoresist of photocuring epoxy resin is usable. Moreover, as the photoresist usable in the present invention, such a non-solvent type photoresist that hardly affects the lower function layer 16 is usable.

In the present invention, a dopant solution is supplied to the trench patterns 18a and 18b illustrated in FIG. 1 by use of the capillary phenomenon, and thus the doping is performed for the function layer along the trench patterns 18a and 18b.

As the dopant usable in the present invention, any dopant is usable as long as necessary luminescence characteristics can be obtained. For example, the dopant can be selected from a daylight fluorescent material, fluorescent whitener, laser dyestuff, organic scintillator, a dyestuff for fluorescence analysis reagent and the like.

More specifically, as the above-described dyestuff, there can be listed Nile Blue, Nile Red, TPB, Coumarin 6, Ketocoumarin, Rubrene, DCM-1 (orange red), Perylene, p-Terphenyl, Polyphenyl 1, Stilbene 1, Stilbene 3, Courmarin 2, Coumarin 47, Coumarin 102, Coumarin 30, Rhodamine 6G, Rhodamine B, Rhodamine 700, Styryl 9, HITCL, IR 140 and the like. However, in the present invention, any dyestuff other than the above-described ones is usable as long as it can give a suitable emission spectrum.

Furthermore, in general, a dyestuff giving a peak of the emission spectrum to the vicinity of approximately 420 nm is usable in order to obtain, for example, luminescence of blue (B) light. Moreover, a dyestuff giving a peak of the emission spectrum to the vicinity of approximately 500 nm is usable in order to obtain, for example, luminescence of green (G) light. Furthermore, a dyestuff giving a peak of the emission spectrum to the vicinity of approximately 600 nm is usable in order to obtain, for example, luminescence of red (R) light. Furthermore, these dyestuffs can be selected appropriately from ones having names and chemical structures, which correspond to the color index (CI), in consideration of the ranges of the emission spectra, the solubilities and the like.

Moreover, as the solvent usable when coating the function layer in the present invention, any solvent known heretofore is usable. For example, there can be listed a hydrocarbon solvent such as amylbenzene, isopropylbenzene, ethylbenzene, xylene, diethylbenzene, cyclohexene, cyclopentane, dipentene, dimethylnaphthalene, a cymene group, camphor oil, petroleum ether, petroleum benzin, solvent naphtha, decalin, decane, tetralin, turpentine oil, kerosene, dodecane, dodecylbenzene, toluene, naphthalene, nonane, pine oil, pinene, methylcyclohexane, p-menthane and ligroin.

Furthermore, as the above-described solvent, it is possible to use a halogenated hydrocarbon solvent such as 2-ethylhexyl chloride, amyl chloride, isopropyl chloride, ethyl chloride, naphthalene chloride, butyl chloride, hexyl chloride, methyl chloride, methylene chloride, o-chlorotoluene, p-chlorotoluene, chlorobenzene, carbon tetrachloride, dichloroethane, dichloroethylene, dichlorotoluene, dichlorobutane, dichloropropane, dichlorobenzene, dibromoethane, dibromobutane, dibromopropane, dibromobenzene, dibromopentane, allyl bromide, isopropyl bromide, ethyl bromide, octyl bromide, butyl bromide, propyl bromide, methyl bromide, lauryl bromide, tetrachloroethane, tetrachloroethylene, tetrabromoethane, tetramethylene chlorobromide, trichloroethane, trichloroethylene, trichlorobenzene, bromochloroethane, 1-bromo-3-chloropropane, bromonaphthalene, bromobenzene, hexachloroethane, and pentamethylene chlorobromide.

Moreover, as the above-described solvent, there can be listed alcohol such as amyl alcohol, allyl alcohol, isoamyl alcohol, isobutyl alcohol, isopropyl alcohol, undecanol, ethanol, 2-ethylbutanol, 2-ethylhexanol, 2-octanol, n-octanol, glycidol, cyclohexanol, 3,5-dimethyl-l-hexyn-3-ol, n-decanol, tetrahydrofurfuryl alcohol, α-terpineol, neopentyl alcohol, nonanol, fusel oil, butanol, furfuryl alcohol, propargyl alcohol, propanol, hexanol, heptanol, benzyl alcohol, pentanol, methanol, methylcyclohexanol, 2-methyl-1-butanol, 3-methyl-2-butanol, 3-methyl-l-butyn-3-ol, 4-methyl-2-pentanol, and 3-methyl-l-pentyn-3-ol.

Furthermore, as the above-described solvent, there can be listed an ether/acetal solvent such as anisole, ethyl isoamyl ether, ethyl-t-butyl ether, ethyl benzyl ether, epoxybutane, a crown ether group, cresyl methyl ether, diisoamyl ether, diisopropyl ether, diethyl acetal, diethyl ether, dioxane, 1,8-cineol, diphenyl ether, dibutyl ether, dipropyl ether, dibenzyl ether, dimethyl ether, tetrahydropyran, tetrahydrofuran, trioxane, bis(2-chloroethyl)ether, phenetole, butyl phenyl ether, furan, furfural, methylal, methyl-t-butyl ether, methylfuran, and monochlorodiethyl ether.

As the above-described solvent, it is possible to similarly use a ketone/aldehyde solvent such as acetylacetone, acetaldehyde, acetophenone, acetone, isophorone, ethyl-n-butylketone, diacetone alcohol, diisobutyl ketone, diisopropyl ketone, diethyl ketone, cyclohexanone, di-n-propyl ketone, phorone, mesityl oxide, methyl-n-amyl ketone, methyl isobutyl ketone, methyl ethyl ketone, methylcyclohexanone, methyl-n-butyl ketone, methyl-n-propyl ketone, methyl-n-hexyl ketone, and methyl-n-heptyl ketone.

As the solvent usable in the present invention, there can be further listed an ester solvent such as diethyl adipate, dioctyl adipate, acetyl triethyl citrate, acetyl tributyl citrate, ethyl acetoacetate, allyl acetoacetate, methyl acetoacetate, methyl abietate, ethyl benzoate, butyl benzoate, propyl benzoate, benzyl benzoate, methyl benzoate, isoamyl isovalerate, ethyl isovalerate, isoamyl formate, isobutyl formate, ethyl formate, butyl formate, propyl formate, hexyl formate, benzyl formate, methyl formate, tributyl formate, ester cinnamate, methyl cinnamate, ethyl cinnamate, acetic acid, amyl acetate, allyl acetate, isoamyl acetate, isobutyl acetate, isopropyl acetate, ethyl acetate, acetic acid-2-ethylhexyl, cyclohexyl acetate, butyl acetate, propyl acetate, benzyl acetate, methyl acetate, methylcyclo-hexyl acetate, isoamyl salicylate, benzyl salicylate, methyl salicylate, ethyl salicylate, diamyl oxalate, diethyl oxalate, dibutyl oxalate, diethyl tartrate, dibutyl tartrate, amyl stearate, ethyl stearate, butyl stearate, dioctyl sebacate, dibutyl sebacate, diethyl carbonate, diphenyl carbonate, dimethyl carbonate, amyl lactate, ethyl lactate, methyl lactate, diethyl phthalate, dioctyl phthalate, dibutyl phthalate, dimethyl phthalate, γ-butyrolactone, isoamyl propionate, ethyl propionate, butyl propionate, ethyl propionate, benzyl propionate, methyl propionate, a borate ester group, dioctyl maleate, dibutyl maeate, diisopropyl malonate, diethyl malonate, dimethyl malonate, isoamyl butyrate, isopropyl butyrate, ethyl butyrate, butyl butyrate, methyl butyrate, and a phosphate ester group.

As the above-described solvent, there can be listed polyhydric alcohol and a derivative thereof, such as ethylene glycol, ethylene glycol dibutyl ether, ethylene glycol diacetate, ethylene glycol dibuthyl ether, ethylene glycol dimethyl ether, ethylene glycol monoacetate, ethylene glycol monoisopropyl ether, ethylene glycol monoethyl ether, ethylene glycol monoethyl ether acetate, ethylene glycol monophenyl ether, ethylene glycol monobutyl ether, ethylene glycol monobutyl ether acetate, ethylene glycol monohexyl ether, ethylene glycol monomethyl ether, ethylene glycol monomethyl ether acetate, ethylene glycol monomethoxy methyl ether, ethylene chlorohydrin, 1,3-octylene glycol, glycerol, glycerol 1,3-diacetate, glycerol dialkyl ether, glycerol fatty acid ester, glycerol triacetate, glycerol trilaurate, glycerol monoacetate, 2-chloro-1,3-propanediol, 3-chloro-1,2-propanediol, diethylene glycol, diethylene glycol ethyl methyl ether, and polypropylene glycol.

Furthermore, as the above-described solvent, there can also be listed a carboxylic acid derivative such as isovaleric acid, isobutyric acid, itaconic acid, 2-ethyl hexanoic acid, 2-ethyl acetic acid, oleic acid, caprylic acid, caproic acid, formic acid, valeric acid, acetic acid, lactic acid, pivalic acid, and propionic acid. There can also be listed a phenol group including ethyl phenol, octyl phenol, catechol, guaiacol, xylenol, p-cumylphenol, cresol, dodecylphenol, naphthol, nonylphenol, phenol, benzylphenol, and p-methoxyethylphenol. There can also be listed a nitrogen-containing compound such as acetonitrile, acetone cyanohydrin, aniline, allylamine, amylamine, isoquinoline, isobutylamine, an isopropanolamine group, isopropylamine, imidazole, N-ethylethanolamine, 2-ethylhexylamine, N-ethylmorpholine, ethylenediamine, caprolactam, quinoline, chloroaniline, ethyl cyanoacetate, diamylamine, isobutylamine, diisopropylamine, diisopropylethylamine, diethanolamine, N,N-diethylaniline, diethylamine, diethylbenzylamine, diethylenetriamine, dioctylamine, cyclohexylamine, triethylamine, triamylamine, trioctylamine, triethanolamine, triethylamine, trioctylamine, tri-n-butylamine, tripropylamine, trimethylamine, toluidine, nitroanisol, picoline, piperazine, pyrazine, pyridine, pyrrolidine, N-phenylmorpholine, morpholine, butylamine, heptylamine, and lutidine. Besides the above-described solvents, a solvent of a sulfur-containing compound, a fluorine-based solvent and the like can also be listed.

Moreover, in the present invention, as the solvent for dissolving the dopant, a solvent that does not adversely affect the function layer serving as a lower layer can be appropriately selected from the above-described solvents for use.

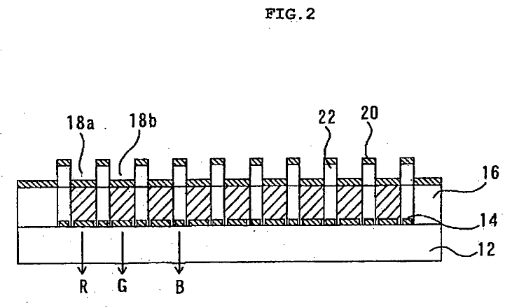

FIG. 2 is a cross-sectional view of the organic EL display device of the present invention, which is illustrated in FIG. 1, taken along the arrow B-B where the patterned anode 14 is cut. Note that, though the organic EL display device of the present invention can be configured as a transistor array in which a plurality of thin film transistors (TFTs) are formed on the substrate 12, the organic EL display device is illustrated in FIG. 2 while omitting the TFT structure for simplifying an explanation thereof. As illustrated in FIG. 2, in the organic EL display device of the present invention, the anode 14 is deposited on the substrate 12, and on the anode 14, the coating-film-formative function layer 16 is formed. On the function layer 16, the trench patterns 18a and 18b formed of the photoresist are formed. Thus, the trench patterns 18a and 18b are configured to be capable of supplying the dopant to the function layer 16 by the capillary phenomenon.

In the embodiment illustrated in FIG. 2, different types of dopant are doped into the trench patterns adjacent to each other. For example, dopant such as Nile Red is doped into the trench pattern 18a to form a R area, and perylene is doped into the trench pattern 18b to form a G area. The doped dopant is dispersed into the inside of the function layer 16 by baking treatment, and thus a configuration is made, in which desired luminescence can be given.

Moreover, the cathode 20 is deposited on the trench patterns 18a and 18b, and thus a configuration is made, in which a current can be supplied to the function layer 16 in cooperation with the anode 14. In the configuration of the bottom emission type, though it is preferable that a material used as the cathode 20 be light-reflective, any conductive material is intrinsically usable. For example, Al, Ca, Sr, LiAl, Ni, Ni/Al, Cr, Ag, MgAg and the like are usable. Moreover, in the present invention, it is desirable that a layer of a material such as an alkali element and an alkaline earth element be directly formed on the function layer 16 for the purpose of improving electron injection efficiency. Furthermore, in another embodiment of the present invention, a conductive organic film including an alkaline metal element or an alkaline earth metal element is usable as the cathode. In such a case, a conductive film of metal such as Al, ITO, Ag, Ni and Cr is usable as an auxiliary conductive layer.

Note that, in another embodiment of the present invention, the cathode illustrated as the upper electrode in FIG. 2 can also be provided on the substrate 12 and formed of a light-transmissive or untransmissive conductive film. Moreover, the anode can also be configured on the side opposite to the cathode 20 by interposing the function layer 16 therebetween, that is, configured as the upper electrode in FIG. 2, and can be formed of a light-reflective or light-transmissive conductive coating film.

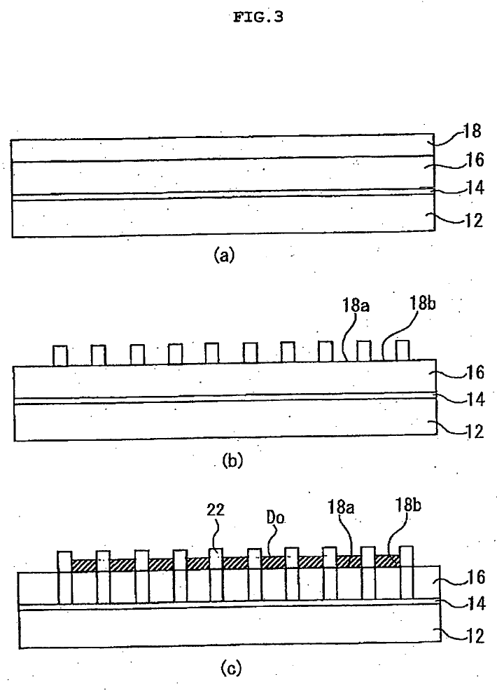

FIGS. 3(a) to 3(c) are views partially showing a manufacturing process of the organic EL display device of the present invention. In the present invention, as shown in FIG. 3(a), the transparent anode 14 such as ITO is formed on the substrate 12, and the function layer 16 is coated on the anode 14 by a method such as, for example, spin coating, and then baked to be formed thereon. Thereafter, the photoresist layer 18 is formed on the formed function layer 16 by use of, for example, epoxy photoresist.

Subsequently, in the present invention, the trench patterns 18a and 18b are formed on the photoresist layer 18 as shown in FIG. 3(b). In this case, ashing treatment can be performed for the surfaces of the photoresist layer 18 and function layer 16 to change chemical affinity of the dopant to the solvent in accordance with the type of solvent for dissolving the dopant. The trench patterns 18a and 18b are separated from each other by the wall 22, and thus are configured to be capable of introducing the mutually different types of dopant Do thereinto. Thereafter, as shown in FIG. 3(c), the solutions of the dopant Do are introduced into the trench patterns 18a and 18b formed on the photoresist layer 18 by use of the capillary phenomenon. Note that, in the present invention, the same type of dopant Do and the different types of dopant Do can be introduced into the trench patterns 18a and 18b.

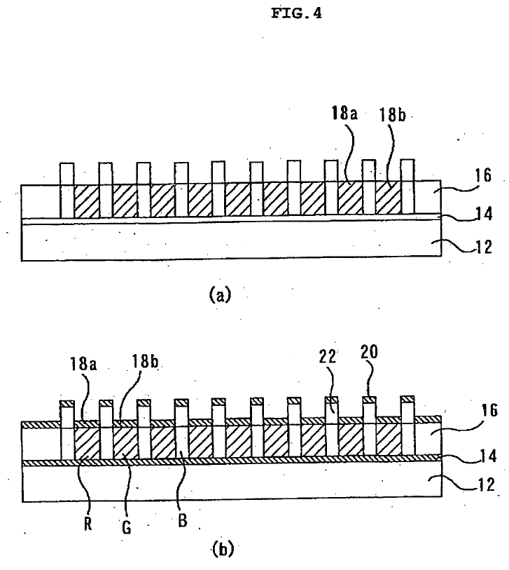

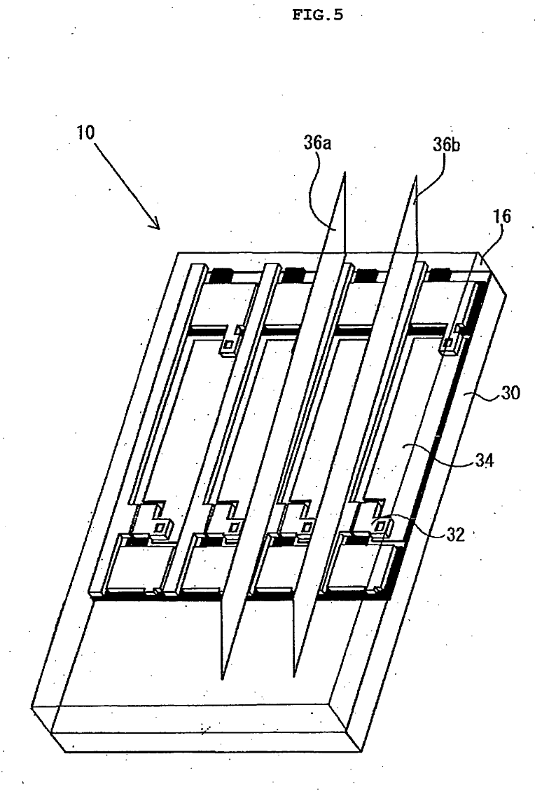

Thereafter, as shown in FIG. 4(a), the baking treatment is performed to disperse the dopant into the function layer 16, thus obtaining desired color patterning. In the embodiment shown in FIGS. 3(a) to 3(c), Nile Red is introduced into the trench 18a to form the R area, and perylene is introduced into the trench 18b to form the G area. Moreover, the dopant does not permeate the lower area 18c of the wall defining the trench patterns 18a and 18b during the baking, and luminescence will not occur therein. Alternatively, in the specific embodiment of the present invention, the luminescence of blue (B) light by polyvinylcarbazole will be observed.

Thereafter, in the present invention, the light-reflective cathode 20 coating the trench patterns 18a and 18b are deposited thereon by a method such as sputtering as shown in FIG. 4(b), thus forming the organic EL device in the present invention. Because the cathode 20 is deposited along the trench patterns, the cathode 20 is cut by the trench patterns, and thus can be formed in a parallel stripe shape. As a result of this, the luminescence of R can be obtained in the trench pattern 18a, the luminescence of G can be obtained in the trench pattern 18b, and the luminescence of B can be obtained in the lower area of the wall 22. Thus, full-color patterning is made possible.

FIG. 5 is a perspective view illustrating a device structure of the organic EL display device of the present invention. As illustrated in FIG. 5, the organic EL display device 10 of the present invention includes the TFTs 32 arrayed in matrix on the substrate 30, and thus is configured to be capable of active matrix drive. The pixel electrodes 34 are formed to be adjacent to the TFTs 32, and the function layer 16 is formed on the pixel electrodes 34. Moreover, the doping is performed for the function layer 16 in accordance with the present invention, and the end positions of the both side walls where the trench patterns for the doping are formed are denoted by the reference numerals 36a and 36b. As illustrated in FIG. 5, the doping in the present invention is performed by use of the trench patterns formed by photolithography, and therefore, it is made possible to perform the doping with extremely high accuracy per pixel unit. Moreover, because it is not necessary to use an expensive shadow mask when the color patterning is performed, it is made possible to manufacture an organic EL display device capable of a color display extremely easily at low cost. As described above, the organic EL display device of the present invention can be applied to any of a passive type and an active type. When the organic EL display device is applied to the active type, it is satisfactory if any of the anode and the cathode may be connected to the TFTS.

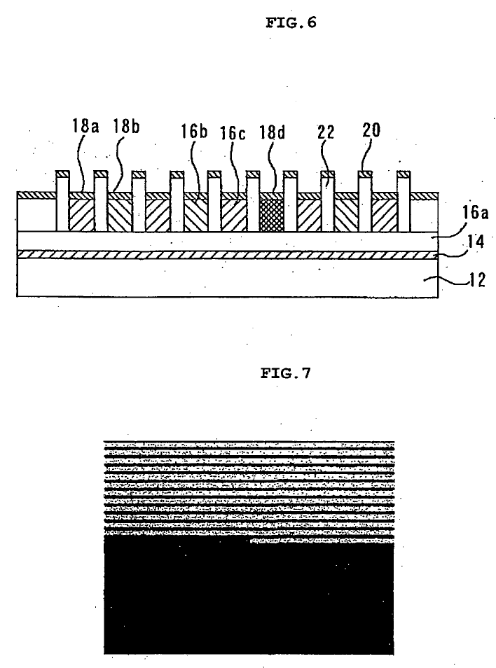

FIG. 6 is a view illustrating a cross-sectional configuration of another embodiment of the organic EL display device of the present invention. In the organic EL display device 10 illustrated in FIG. 6, the transparent conductive electrode 14 is formed on the substrate 12, and the first function layer 16a is formed on the conductive electrode 14. The photoresist layer 18 is formed on the first function layer 16a, and the trench patterns 18a and 18b are formed on the photoresist layer 18.

Furthermore, in the organic EL display device 10 illustrated in FIG. 6, materials forming the second and third function layers 16b and 16c are introduced along the trench patterns 18a and 18b. In the present invention, the function layers 16b and 16c introduced into the trench patterns 18a and 18b may be the same or different from each other. In the case of introducing the different function layers 16b and 16c, function layers giving emission spectra different for each of the trench patterns 18a and 18b can be introduced, and the color patterning can be completed at the manufacturing stage. Furthermore, in the embodiment illustrated in FIG. 6, the dopant Do can be further introduced by use of the capillary phenomenon in order to obtain desired luminescence. In FIG. 6, the dopant Do is introduced into the trench pattern 18d in accordance with the present invention, and thus a configuration is made, in which the desired luminescence can be obtained.

### EXAMPLES

Although the present invention will be described below by means of concrete examples, the present invention is not limited to the following examples, either.

### Example 1

An ITO film was deposited on a glass substrate by sputtering so as to have a film thickness of approximately 50 nm, and pixel electrodes were formed. A solution obtained by mixing polyvinylcarbazole as a carrier transport material and PBD as an electron transport material was spin-coated on the obtained ITO film, and then baking was performed therefor. Thus, a function layer having a film thickness of approximately 100 nm was formed. A photoresist layer was formed on the obtained function layer by use of epoxy photoresist (SU-8 made by Microchem Corp.). After baking, a trench pattern was patterned so that a pitch thereof was set at 190 ppi or 340 ppi. After the patterning, O₂ ashing was performed for the surface of the trench pattern and the surface of the exposed function layer, thus imparting hydrophilicity thereto.

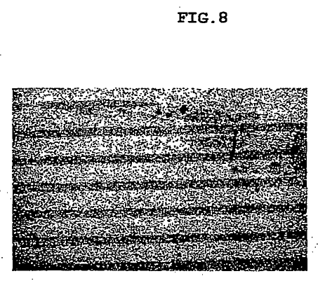

An acetic anhydride solution of Methylene Blue (2 mass %) was introduced into the obtained trench patterns by use of the capillary phenomenon, and the doping was performed. FIG. 7 shows the state of the dopant solution that is permeating the trench pattern during the doping. The doping example shown in FIG. 7 is one obtained in the case of introducing the dopant solution into the trench pattern at the pitch of 190 ppi by use of the capillary phenomenon. FIG. 8 shows that it is possible to perform doping along the trench pattern well according to the present invention.

After the doping, baking was performed at 130 for 30 minutes. Thus, the solvent was dried, and the dopant was dispersed. Thereafter, MgAg was deposited by sputtering to form a cathode, followed by formation of a protective layer under a N₂ atmosphere. Thus, the organic EL display device of the present invention was manufactured. A direct current was supplied to the manufactured organic EL device. Then, good luminescence of B was obtained.

### Examples 2 and 3

Dopant solutions having compositions in Table 1 shown below were prepared, organic EL display devices were manufactured similarly to Example 1, and luminescence characteristics thereof were observed. Then, good luminescence of R and G were obtained.

### Example 4

In Example 4, doping was performed by use of the capillary phenomenon similarly to Example 1 except that a trench pattern was prepared at the pitch of 340 ppi. Then, good doping was similarly possible.

TABLE 1

| | Dopant | Solvent | Concentration |
|---|---|---|---|
| Example 2 | Nile Red | Acetic | 2 mass % |
| | | Anhydride | |
| Example 3 | Perylene | Acetic | 2 mass % |
| | | Anhydride | |
| Example 4 | Methylene | Acetic | 2 mass % |
| | Blue | Anhydride | |

### Example 5

An organic EL device was formed similarly to Example 1 except that a trench pattern was formed in a comb tooth shape as illustrated in FIG. 1, a solution containing Nile Red of 2 mass % was introduced from one end of the pattern and a solution containing Perylene of 2 mass % was doped from the other end. When luminescence characteristics thereof were observed, luminescence of R, G and B were observed. Because the Nile Red and the Perylene have higher luminescence efficiencies than that of the polyvinylcarbazole, the luminescence of R and G occurred priorly. Moreover, because the dopant was not doped in the area where the wall portions of the trenches were formed, the luminescence of B by the polyvinylcarbazole was observed. These are reasons of the luminescence of each color. Table 2 shows results obtained with regard to the types of dopant and luminescence characteristics of the above-described Examples 1 to 4.

TABLE 2

| | | | | Display |
|---|---|---|---|---|
| | | Luminous | Resolution | Character- |
| | Dopant | Area | (ppi) | istics |
| Example 1 | Nile Blue | B | 190 | Good |
| Example 2 | Nile Red | B, R | 190 | Good |
| Example 3 | Perylene | B, G | 190 | Good |
| Example 4 | Nile Blue | B | 340 | Good |
| Example 5 | Nile Red, | R, G and B | 190 | Good |
| | Perylene | | | |

As described above, according to the present invention, high-definition color patterning can be formed for the organic EL display device easily at low cost.

As above, the present invention has been described in detail by means of the embodiments illustrated in the drawings. However, the present invention is not limited to the embodiments illustrated in the drawings. With regard to the configuration of the details, the structure, configuration, material, manufacturing process order of the organic EL function layer and the like, any can be appropriately applied as long as a similar configuration can be obtained. Moreover, if the trench pattern is formed in a color filter shape so as to correspond to the pixels in the present invention, it is possible to perform good color patterning.

Although the preferred embodiments of the present invention have been described in detail, it should be understood that various changes, substitutions and alternations can be made therein without departing from spirit and scope of the inventions as defined by the appended claims.

1. An organic light emitting diode device, comprising:
a substrate;
a first electrode formed on the substrate;
an organic electroluminescent function layer formed on the substrate;
a trench pattern formed adjacently to the function layer; and
a second electrode layer formed on the function layer and the trench pattern.

2. The organic electroluminescent device according to claim 1,
wherein the function layer contains any one of polymer and oligomer, each having an amine derivative structure.

3. The organic electroluminescent device according to claim 1,
wherein different types of dopant are contained in areas of the function layer, the areas being adjacent to each other while being spaced by a wall of the trench pattern.

4. The organic electroluminescent device according to claim 1 wherein a doping concentration in the function layer under the wall forming the trench pattern is lower than in other portions.

5. A method for manufacturing an organic light emitting diode device, the method comprising the steps of:
forming a first electrode on a substrate;
forming an organic electroluminescent function layer and a trench pattern on the electrode; and
forming a second electrode layer on the function layer and the trench pattern.

6. The manufacturing method according to claim 5,
wherein the step of forming a function layer and a trench pattern includes the steps of: forming the function layer; forming a photoresist layer on the function layer; and patterning the photoresist layer into the trench pattern.

7. The manufacturing method according to claim 5, further comprising the step of introducing, along the trench pattern, at least a second function layer having a composition different from a composition of the function layer.

8. The manufacturing method according to claim 5, further comprising the step of performing doping for the function layer by supplying a dopant solution along the trench pattern.

9. The manufacturing method according to claim 8,
wherein the step of performing doping for the function layer by supplying a dopant solution includes the steps of: supplying the dopant solution along the trench pattern; and dispersing the dopant into the function layer by heating the function layer.

10. The manufacturing method according to claim 8,
wherein the step of performing doping includes the step of supplying different types of dopant into areas of the function layer, the areas being spaced by a wall of the trench pattern.

11. The organic electroluminescent device according to claim 2 wherein a doping concentration in the function layer under the wall forming the trench pattern is lower than in other portions.

12. The organic electroluminescent device according to claim 3 wherein a doping concentration in the function layer under the wall forming the trench pattern is lower than in other portions.
